(19) United States
(12) Patent Application Publication
(10) Pub. No.: US 2008/0290502 A1
(43) Pub. Date: Nov. 27, 2008

(54) INTEGRATED CIRCUIT PACKAGE WITH SOLDERED LID FOR IMPROVED THERMAL PERFORMANCE

(76) Inventor: Zafer Kutlu, Menlo Park, CA (US)

Correspondence Address: LSI Logic Corporation;Corporate Legal Department, Intellectual Property Services Group, 1621 Barber Lane, M/S D-106, Milpitas, CA, 95035, US

(21) Appl. No.: 11/753,591

(22) Filed: May 25, 2007

(51) Int. Cl. H01L 23/36; H01L 21/58; H01L 23/488

(52) U.S. Cl. 257/713; 257/772; 438/119; 257/E21.505; 257/E23.101; 257/E23.023

(57) ABSTRACT

An integrated circuit die includes a circuit surface and a back surface opposite the circuit surface. An underbump metallurgy is formed on a back surface. A layer of solder is formed on the underbump metallurgy.

### BACKGROUND OF THE INVENTION

1. Field of the Invention

The present invention is directed to the design and manufacture of integrated circuits. More specifically, but without limitation thereto, the present invention is directed to an integrated circuit package.

2. Description of Related Art

In previous construction techniques for packaging a flipchip integrated circuit die, a lid is attached to the backside of the die by a thermally conductive adhesive between the die and the lid. As integrated circuit die technology reduces the size of silicon, faster performance is achieved with higher density and smaller chips. The faster performance leads to increased power and the need for increased heat dissipation from a smaller chip area and package.

### SUMMARY OF THE INVENTION

In one embodiment, an integrated circuit die includes a circuit surface and a back surface opposite the circuit surface. An underbump metallurgy is formed on the back surface. A layer of solder is formed on the underbump metallurgy.

In another embodiment, a method of making an integrated circuit die includes forming a circuit surface and a back surface opposite the circuit surface on a die substrate. An underbump metallurgy is formed on the back surface. A layer of solder is formed on the underbump metallurgy.

### BRIEF DESCRIPTION OF THE DRAWINGS

The present invention is illustrated by way of example and not limitation in the accompanying figures, in which like references indicate similar elements throughout the several views of the drawings, and in which:

FIG. 1 illustrates a side view of a flip-chip integrated circuit package of the prior art with a thermally conductive adhesive;

FIG. 2 illustrates a side view of the flip-chip integrated circuit package of FIG. 1 without a lid;

FIG. 3 illustrates a magnified side view of an integrated circuit die with an additional underbump metallurgy formed on the back of the die;

FIG. 4 illustrates a magnified side view of the integrated circuit die of FIG. 3 after photo resist and etching;

FIG. 5 illustrates a magnified side view of the integrated circuit die of FIG. 4 after forming solder bumps on the circuit surface and a continuous layer of solder on the back surface underbump metallurgy structure;

FIG. 6 illustrates a side view of an integrated package with a metal lid soldered to the back of the integrated circuit die of FIG. 5;

FIG. 7 illustrates a magnified side view of the integrated circuit die of FIG. 4 after forming solder bumps on the circuit surface and a plurality of solder bumps on the back surface underbump metallurgy structure;

FIG. 8 illustrates a side view of an integrated package with a heat sink structure soldered to the back of the integrated circuit die of FIG. 7;

FIG. 9 illustrates a flow chart for making the integrated circuit package of FIG. 6 or FIG. 8; and

FIG. 10 illustrates a side view of the integrated circuit package of FIG. 6 with a grounded lid.

Elements in the figures are illustrated for simplicity and clarity and have not necessarily been drawn to scale. For example, the dimensions of some elements in the figures may be exaggerated relative to other elements to point out distinctive features in the illustrated embodiments of the present invention.

### DESCRIPTION OF THE ILLUSTRATED EMBODIMENTS

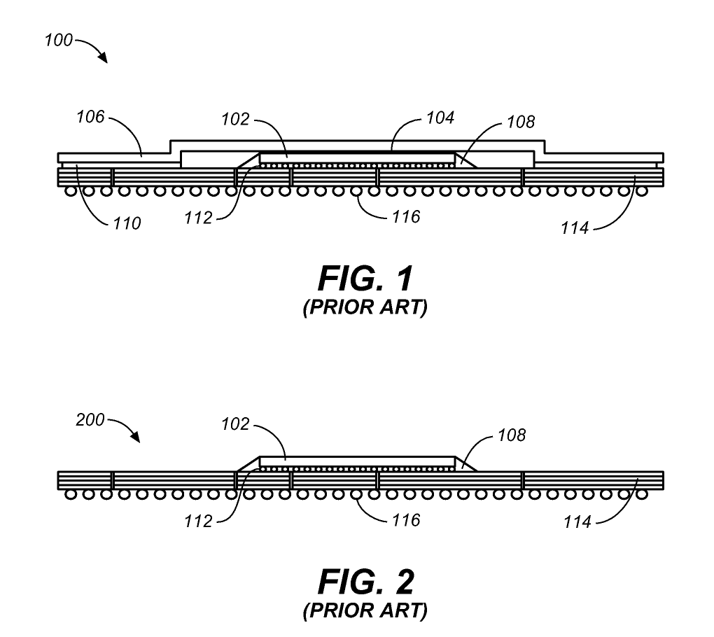

FIG. 1 illustrates side view 100 of a flip-chip integrated circuit package of the prior art with a thermally conductive adhesive. Shown in FIG. 1 are an integrated circuit die 102, a thermal adhesive compound 104, a lid 106, underfill epoxy 108, lid seal epoxy 110, solder bumps 112, a substrate 114, and solder balls 116.

A disadvantage of using the thermally conductive adhesive 104 in the flipchip package 100 is that the thermally conductive adhesive 104 has a bulk thermal conductivity of typically about one to three W/mK (Watts per meter Kelvin). Further, the contact resistance of the thermal adhesive reduces the heat dissipation capability of the thermally conductive adhesive 104 by about 50 percent. As a result, the thermal conductivity between the integrated circuit die 102 and the lid 106 is insufficient to meet the heat dissipation requirement of the flipchip package when operating the integrated circuit die 102 within power specifications. To provide increased heat dissipation for smaller dies and packages with increased power, higher thermal conductivity and lower contact resistance is needed.

One method of increasing thermal conductivity developed in the prior art is to increase the filler content of the thermally conductive adhesive 104. However, increasing the filler content significantly reduces flow and dispensing properties of the thermal adhesive compound 104. Also, higher filler content increases the possibility of delamination of the thermal adhesive compound 104 from the lid or from the integrated circuit die 102. Further, increased filler content does not improve the contact resistance of the thermal adhesive compound 104 that reduces the effective thermal conductivity between the die and the lid. Another problem with increased filler content is that the thickness of the thermal adhesive compound 104 may not be reduced to less than about 50 microns. To avoid the problems encountered with the thermal adhesive compound 104, the lid may be omitted from the integrated circuit package.

FIG. 2 illustrates a side view 200 of the flip-chip integrated circuit package of FIG. 1 without a lid. Shown in FIG. 2 are an integrated circuit die 102, underfill epoxy 108, solder bumps 112, a substrate 114, and solder balls 116.

In FIG. 2, the lid 106 and lid seal epoxy 110 are omitted from the package of FIG. 1 to improve heat dissipation performance of the integrated circuit die 102. However, if no lid is attached, the integrated circuit die 102 is susceptible to damage from handling during board level assembly and test processes as well as from accidental damage by an end user. Also, there is tensile stress on the integrated circuit die 102 due to the flipchip package construction. Because the integrated circuit die 102 is generally very brittle, a small external force/stress may result in breakage of the integrated circuit die 102. In addition, the identification marking typically made on the back surface of the integrated circuit die 102 may create stress concentration points that increase the risk of die fracture.

A preferred method is described below that overcomes the disadvantages of the prior art by leveraging the same techniques used in manufacturing flipchip integrated circuit packages. In addition, the method described below may also be used to improve thermal conductivity in other types of integrated circuit packages within the scope of the appended claims.

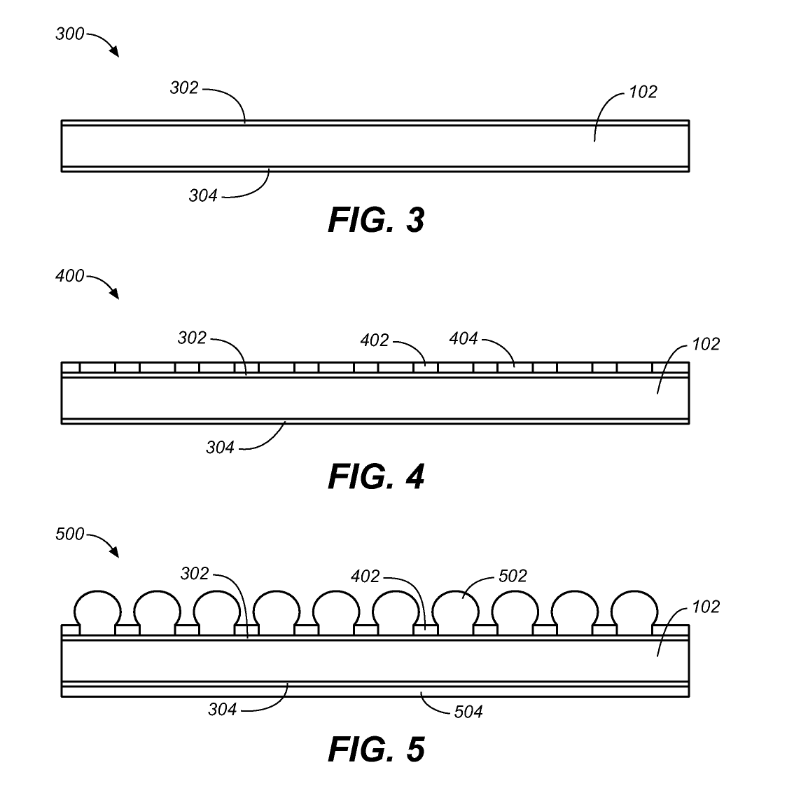

FIG. 3 illustrates a magnified side view 300 of an integrated circuit die with an additional underbump metallurgy formed on the back of the die. Shown in FIG. 3 are an integrated circuit die 102 and underbump metallurgy (UBM) structures 302 and 304.

Each of the underbump metallurgy (UBM) structures 302 and 304 is a multilayer deposition, or stack, of thin film interface metals such as titanium, copper, and nickel. In a typical flipchip package of the prior art, the underbump metallurgy (UBM) structure 302 is deposited on the circuit surface of the integrated circuit die 102. The underbump metallurgy (UBM) structure 302 is then etched to form solder bumps that make electrical contact between the integrated circuit die 102 and the integrated circuit package as shown in FIG. 1.

In one embodiment, the underbump metallurgy (UBM) structure 304 is deposited on the back surface of the integrated circuit die 102 opposite to the circuit surface in addition to the underbump metallurgy (UBM) structure 302 deposited on the circuit surface of the integrated circuit die 102. The underbump metallurgy (UBM) structure 304 on the back surface of the integrated circuit die 102 may be formed, for example, according to the same techniques used to form the underbump metallurgy (UBM) structure 302. In contrast to the circuit surface, the back surface of the integrated circuit die 102 is not typically electrically connected to circuits inside the integrated circuit die. However, an electrical connection to the back surface may be used in some embodiments, for example, as a ground or an electromagnetic interference (EMI) shield.

FIG. 4 illustrates a magnified side view 400 of the integrated circuit die of FIG. 3 after photo resist and etching. Shown in FIG. 4 are an integrated circuit die 102, underbump metallurgy (UBM) structures 302 and 304, a photo resist layer 402, and holes 404.

In FIG. 4, the photo resist layer 402 is formed on the underbump metallurgy structure 302 and etched to form the holes 404 on the circuit surface of the integrated circuit die 102. No photo resist layer is required on the underbump metallurgy structure 304 on the back surface of the die 102; however, a photo resist layer may be formed on the underbump metallurgy structure 304 to practice other embodiments within the scope of the appended claims.

FIG. 5 illustrates a magnified side view 500 of the integrated circuit die of FIG. 4 after forming solder bumps on the circuit surface and a continuous layer of solder on the back surface underbump metallurgy structure. Shown in FIG. 5 are an integrated circuit die 102, underbump metallurgy (UBM) structures 302 and 304, a photo resist layer 402, solder bumps 502, and a solder layer 504.

In FIG. 5, the solder bumps 502 are plated on the underbump metallurgy (UBM) structure 302 through the holes in the photo resist layer, for example, by a bumping process, to make electrical contact between the integrated circuit die 102 and the integrated circuit package substrate. The same process may be used to plate the continuous solder layer 504 on the underbump metallurgy (UBM) structure 304 without the photo resist. After the bumping process, the photo resist layer 402 is removed, for example, by an etching process.

During package assembly, the lid 106 in FIG. 1 is soldered to the back of the integrated circuit die 102 with the solder layer 504, for example, by the same ball attach reflow process used in the package assembly process. The lid 106 may be soldered to the back surface of the integrated circuit die 102 using a solder layer thickness, for example, of less than five microns. The solder layer 504 has a thermal conductivity of about 50-60 W/mK and low contact resistance. As a result, the heat dissipation capability of the flipchip package in FIG. 1 may be improved by an order of magnitude or more.

In one embodiment, an integrated circuit package includes an integrated circuit die having a circuit surface and a back surface opposite the circuit surface. An underbump metallurgy is formed on the back surface. A layer of solder is formed on the underbump metallurgy.

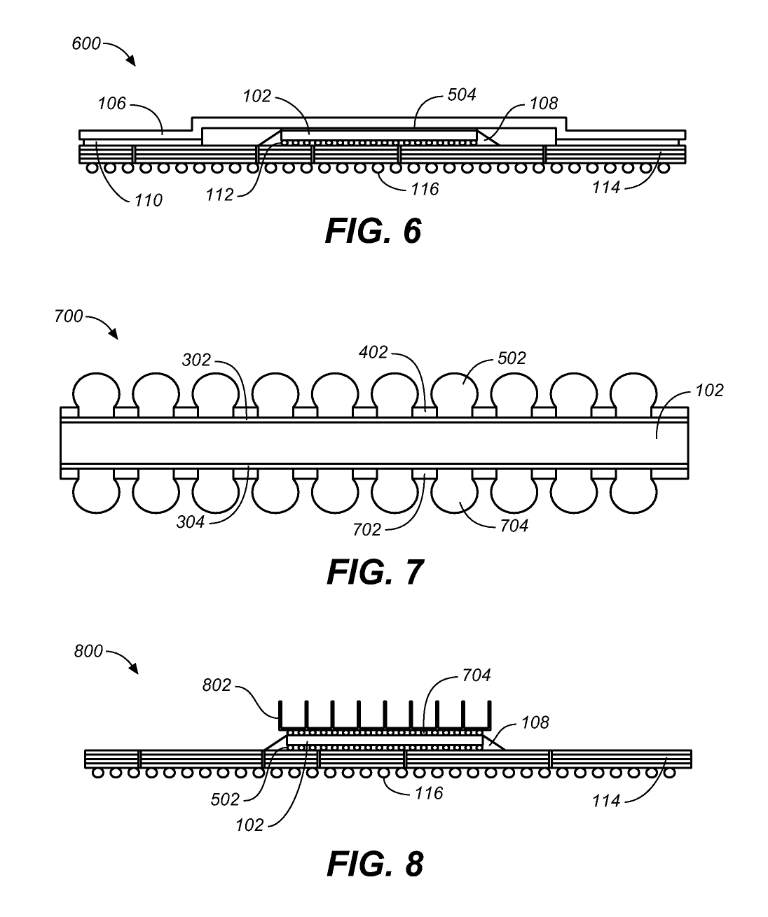

FIG. 6 illustrates a side view 600 of an integrated package with a metal lid soldered to the back of the integrated circuit die of FIG. 5. Shown in FIG. 6 are an integrated circuit die 102, a metal lid 106, an underfill adhesive 108, a lid seal 110, a substrate 114, solder balls 116, solder bumps 502, and a solder layer 504.

In FIG. 6, the die 102 in FIG. 5 has been inverted so that the circuit surface is facing down, hence the term “flip-chip”. The thermal compound of FIG. 1 has been replaced by the solder layer 504, advantageously increasing the thermal conductivity while reducing the contact resistance. As a result, the integrated circuit package of FIG. 6 has superior heat dissipation performance compared to that of FIG. 1. In one embodiment, the layer of solder is a continuous layer of solder, as in the example of the solder layer 504 in FIG. 5. In other embodiments, the layer of solder may be discontinuous, such as the individual solder bumps 704 in FIG. 7.

FIG. 7 illustrates a magnified side view 700 of the integrated circuit die of FIG. 4 after forming solder bumps on the circuit surface and a plurality of solder bumps on the back surface underbump metallurgy structure. Shown in FIG. 7 are an integrated circuit die 102, underbump metallurgy (UBM) structures 302 and 304, photo resist layers 402 and 702, and individual solder bumps 502 and 704.

In the embodiment of FIG. 7, the layer of solder consists of the plurality of solder bumps 704. The solder bumps 704 are plated on the underbump metallurgy (UBM) structure 304 on the back surface of the integrated circuit die 102, for example, in the same manner as the solder bumps 502 on the underbump metallurgy (UBM) structure 302. After the bumping process, the photo resist layers 402 and 702 are removed, for example, by an etching process. During package assembly, the lid 106 in FIG. 1 is soldered to the back of the integrated circuit die 102, for example, by the same ball attach reflow process used in the package assembly process.

FIG. 8 illustrates a side view 800 of an integrated package with a heat sink structure soldered to the back of the integrated circuit die of FIG. 7. Shown in FIG. 8 are an integrated circuit die 102, an underfill adhesive 108, a lid seal 110, a substrate 114, solder balls 116, solder bumps 502 and 704, and a heat sink structure 802.

In FIG. 8, the integrated circuit die 102 in FIG. 7 has been inverted so that the circuit surface is facing down. In this embodiment, the lid covering the integrated circuit die 102 is the heat sink structure 802. The heat sink structure 802 has a greater surface area for dissipating heat from the integrated circuit die 102 compared to the lid 106 of FIG. 1. The heat sink structure 802 is soldered to back of the integrated circuit die 102 by the individual solder bumps 704. In another embodiment, the same thermal compound used in FIG. 1 is added between the solder bumps 704 to improve thermal conductivity. As a result of these improvements, the integrated circuit package of FIG. 8 has superior heat dissipation performance compared to that of FIGS. 1 and 2. The heat sink structure 802 may be, for example, a finned heat sink made of, for example, copper or a copper alloy. In this embodiment, the layer of solder formed on the back surface of the integrated circuit die 102 consists of the plurality of solder bumps 704 formed on the underbump metallurgy (UBM) structure 304 in FIG. 7.

In another embodiment, a method of making an integrated circuit package includes the following steps. An integrated circuit die is provided having a circuit surface and a back surface opposite the circuit surface. An underbump metallurgy is formed on the back surface. A layer of solder is formed on the underbump metallurgy.

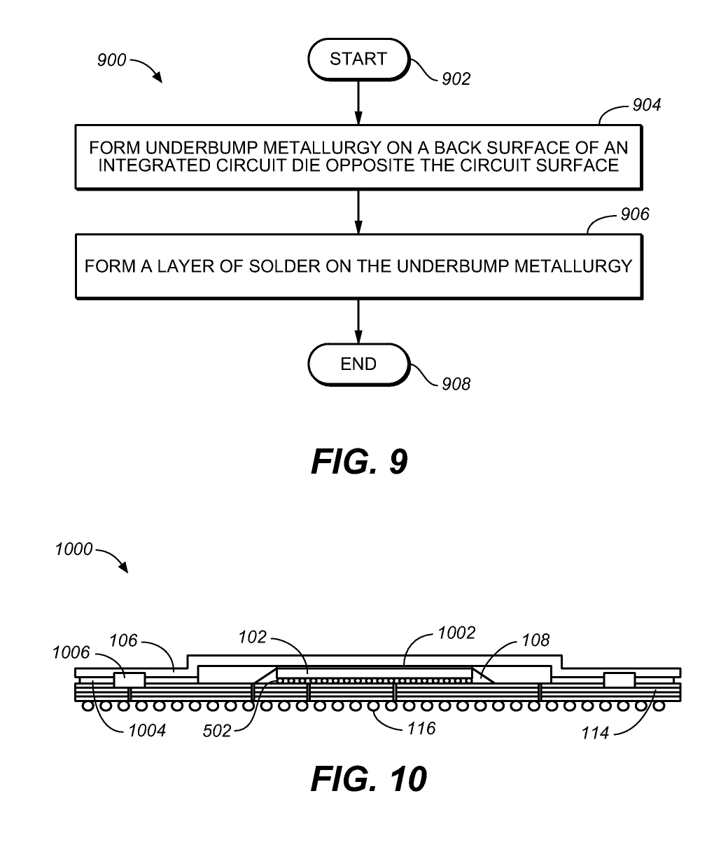

FIG. 9 illustrates a flow chart 900 for making the integrated circuit package of FIG. 6 or FIG. 8.

Step 902 is the entry point of the flow chart 900.

In step 904, underbump metallurgy 304 is formed on a back surface of an integrated circuit die opposite the circuit surface, for example, by the same process used to form the underbump metallurgy on the circuit surface in the flipchip package of FIG. 1.

In step 906, the layer of solder is formed on the underbump metallurgy 304, for example, by a plating process. The layer of solder may be, for example, the continuous solder layer of FIG. 5 or the plurality of solder bumps 704 of FIG. 7.

Step 908 is the exit point of the flow chart 900.

FIG. 10 illustrates a side view of the integrated circuit package of FIG. 6 with a grounded lid. Shown in FIG. 10 are an integrated circuit die 102, a metal lid 106, an underfill adhesive 108, a package substrate 114, solder balls 116, solder bumps 502, a layer of solder 1002, a non-conductive adhesive 1004, and an electrical connection 1006.

In FIG. 10, the layer of solder 1002 is the continuous solder layer of FIG. 5. In other embodiments, the layer of solder 1002 may be the plurality of solder bumps 704 of FIG. 7. The metal lid 106 is connected with the non-conductive adhesive 1004 to the package substrate. The conductive material 1006 connects the metal lid 106 to the electrical connection, ground, or another circuit connection in the top metal layer of the package substrate 114. Alternatively, an electrically conductive lid attach epoxy or other conductive material may be used in specific regions on the package substrate 114 to electrically connect the metal lid 106 to a ground plane or to connections inside the package substrate 114 instead of or in addition to the electrical connection 1006.

By using the layer of solder 1002 between the integrated circuit die 102 and the metal lid 106, the grounded metal lid may be used as a ground plane on the back side of the integrated circuit die 106.

In a further embodiment, an integrated circuit die includes a circuit surface and a back surface opposite the circuit surface, for example, as shown in FIG. 3. An underbump metallurgy is formed on the back surface, and a layer of solder is formed on the underbump metallurgy. The layer of solder may be used, for example, as a ground plane for the integrated circuit die as well as for incorporating the die into various packaging schemes.

In another embodiment, a method of making an integrated circuit die includes forming a circuit surface and a back surface opposite the circuit surface on a die, for example, as shown in FIG. 3. An underbump metallurgy is formed on the back surface, and a layer of solder is formed on the underbump metallurgy.

Although the method illustrated by the flowchart description above is described and shown with reference to specific steps performed in a specific order, these steps may be combined, sub-divided, or reordered without departing from the scope of the claims. Unless specifically indicated herein, the order and grouping of steps is not a limitation of the present invention.

While the invention herein disclosed has been described by means of specific embodiments and applications thereof, numerous modifications and variations could be made thereto by those skilled in the art without departing from the scope of the invention set forth in the following claims.

The specific embodiments and applications thereof described above are for illustrative purposes only and do not preclude modifications and variations that may be made within the scope of the following claims.

What is claimed is:

1. An integrated circuit package comprising:
an integrated circuit die having a circuit surface and a back surface opposite the circuit surface;
an underbump metallurgy formed on the back surface; and
a layer of solder formed on the underbump metallurgy.

2. The integrated circuit package of claim 1 further comprising a metal lid soldered to the underbump metallurgy with the layer of solder.

3. The integrated circuit package of claim 2 further comprising a package substrate fastened to the metal lid.

4. The integrated circuit package of claim 3 further comprising an electrical connection formed between the metal lid and the package substrate.

5. The integrated circuit package of claim 3 further comprising an electrical connection formed between the metal lid and a back side of an integrated circuit die.

6. The integrated circuit package of claim 3 further comprising an adhesive for fastening the package substrate to the metal lid.

7. The integrated circuit package of claim 1, the layer of solder comprising a continuous solder layer.

8. The integrated circuit package of claim 1, the layer of solder comprising a plurality of solder bumps.

9. The integrated circuit package of claim 8 further comprising a thermal compound between the solder bumps.

10. The integrated circuit package of claim 1 further comprising a heat sink structure soldered to the underbump metallurgy formed on the back surface of the integrated circuit die.

11. A method of making an integrated circuit package comprising steps of:
providing an integrated circuit die having a circuit surface and a back surface opposite the circuit surface;
forming an underbump metallurgy on the back surface; and
forming a layer of solder on the underbump metallurgy.

12. The method of claim 11 further comprising a step of soldering a metal lid to the underbump metallurgy with the layer of solder.

13. The method of claim 12 further comprising a step of fastening a package substrate to the metal lid.

14. The method of claim 13 further comprising a step of forming an electrical connection between the metal lid and the package substrate.

15. The method of claim 13 further comprising a step of forming an electrical connection between the metal lid and a back side of an integrated circuit die.

16. The method of claim 13 further comprising a step of fastening the package substrate to the metal lid by an electrically conductive adhesive.

17. The method of claim 11 further comprising a step of forming the layer of solder as a continuous solder layer.

18. The method of claim 11 further comprising a step of forming the layer of solder as a plurality of solder bumps.

19. The method of claim 11 further comprising a step of forming a thermal compound between the solder bumps.

20. The method of claim 11 further comprising a step of soldering a heat sink structure to the underbump metallurgy formed on the back surface of the integrated circuit die.

21. An integrated circuit die comprising:
a circuit surface and a back surface opposite the circuit surface;
an underbump metallurgy formed on the back surface; and
a layer of solder formed on the underbump metallurgy.

22. A method of making an integrated circuit die comprising:
forming a circuit surface and a back surface opposite the circuit surface on a die substrate;
forming an underbump metallurgy on the back surface; and
forming a layer of solder on the underbump metallurgy.
